(19) United States
(12) Patent Application Publication
(10) Pub. No.: US 2025/0157775 A1
(43) Pub. Date: May 15, 2025

(54) FIXED POSITION FILAMENT

(71) Applicant: Axcelis Technologies, Inc., Beverly, MA (US)

(72) Inventor: Steve T. Drummond, Merrimac, MA (US)

(21) Appl. No.: 18/944,039

(22) Filed: Nov. 12, 2024

Related U.S. Application Data
(60) Provisional application No. 63/598,566, filed on Nov. 14, 2023.

(51) Int. Cl. H01J 1/26; H01J 37/30; H01J 37/317

(52) U.S. Cl. CPC H01J 1/26; H01J 37/3007; H01J 37/3171

(57) ABSTRACT

A cathode filament device for an indirectly heated cathode has a first and second filament rods having respective first and second engagement portions. The first engagement portion has a first engagement body with first and second positioning features extending from the first engagement body. The second engagement portion has at least a second engagement body. Third and fourth positioning features may extend from the second engagement body. First and second clamping members have respective clamping surfaces configured to selectively engage the respective first and second engagement bodies. At least the first positioning feature limits a translation of the first filament rod with respect to the first clamping member along a first axis. The second, third, and fourth positioning features may further limit the translation and secure a position of a filament coupled to the first and second filament rods.

### REFERENCE TO RELATED APPLICATIONS

This application claims the benefit of U.S. Provisional Application No. 63/598,566 filed Nov. 14, 2023, entitled “FIXED POSITION FILAMENT”, the contents of which are herein incorporated by reference in their entirety.

### TECHNICAL FIELD

The present invention relates generally to ion implantation systems, and more specifically to an improved apparatus and method for accurately aligning a filament in heated cathode for an ion source of an ion implantation system.

### BACKGROUND

In the manufacture of semiconductor devices, ion implantation is used to dope semiconductors with impurities. Ion implantation systems are often utilized to dope a workpiece, such as a semiconductor wafer, with ions from an ion beam, in order to either produce n- or p-type material doping, or to form passivation layers during fabrication of an integrated circuit. Such beam treatment is often used to selectively implant the wafers with impurities of a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material wafer, whereas a “p-type” extrinsic material wafer often results from ions generated with source materials such as boron, gallium, or indium.

A typical ion implanter includes an ion source, an ion extraction device, a mass analysis device, a beam transport device and a wafer processing device. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, semiconductor wafers are transferred in to and out of the wafer processing device via a wafer handling system, which may include one or more robotic arms, for placing a wafer to be treated in front of the ion beam and removing treated wafers from the ion implanter.

Ion sources (commonly referred to as arc discharge ion sources) generate ion beams used in implanters and can include heated filament cathodes for creating ions that are shaped into an appropriate ion beam for wafer treatment. U.S. Pat. No. 5,497,006 to Sferlazzo et al., for example, discloses an ion source having a cathode supported by a base and positioned with respect to a gas confinement chamber for ejecting ionizing electrons into the gas confinement chamber. The cathode of the Sferlazzo et al. patent is a tubular conductive body having an endcap that partially extends into the gas confinement chamber.

External alignment fixtures and adjustment schemes are conventionally used to align various components associated with the ion source. Such implementations of external alignment fixtures can introduce numerous errors into the alignment process. Further, the external alignment fixtures can be misplaced or misused by operators, thus leading to repeatability issues and introducing significant errors into the alignment process.

### SUMMARY

The present disclosure thus provides a system and apparatus for accurately positioning a filament with respect to a cathode of an ion source, thus providing a repeatable alignment of the filament with respect to the cathode when replacing or otherwise maintaining the cathode and/or filament. Accordingly, the following presents a simplified summary of the disclosure in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

In accordance with one aspect of the disclosure, a cathode filament device is provided for an indirectly heated cathode. The cathode filament device, for example, comprises a first filament rod having a first end and a second end along a first axis. The first filament rod comprises a first engagement portion proximate to the first end, wherein the first engagement portion comprises a first engagement body and a first positioning feature extending from the first engagement body. A filament is further operably coupled to the first filament rod proximate to the second end of the first filament rod.

According to one example, a first clamping member of the cathode filament device is provided, wherein the first engagement body is configured to selectively mate with the first clamping member. The first positioning feature, for example, is configured to limit a translation of the first filament rod with respect to the first clamping member in at least a first direction along the first axis. The first filament rod, for example, can further comprise a second positioning feature extending from the first engagement portion, wherein the second positioning feature is configured to limit a translation of the first filament rod with respect to the first clamping member in a second direction along the first axis, wherein the second direction is opposite the first direction.

The first positioning feature and the second positioning feature, for example, can respectively comprise one or more of a tab, a rod, a collar, a flange, and a step extending outwardly from the first engagement portion. In one example, the first engagement portion defines a first diameter of the first filament rod, wherein the first positioning feature and the second positioning feature define a second diameter of the first filament rod, and wherein the second diameter is greater than the first diameter.

In another example, the first engagement portion is cylindrical having a first engagement diameter. As such, the first positioning feature, for example, can comprise a first flange having a first positioning diameter, wherein the first positioning diameter is greater than the first engagement diameter. The first filament rod, for example, can further comprise a second positioning feature extending from the first engagement body, wherein the second positioning feature defines a filament rod diameter. The filament rod diameter, for example, is greater than the first engagement diameter, and the second positioning feature is configured to limit a translation of the first filament rod with respect to the first clamping member in a second direction along the first axis, wherein the second direction is opposite the first direction.

The cathode filament device can further comprise a second filament rod having a third end and a fourth end along a second axis. The second filament rod, for example, can have a second engagement portion proximate to the third end, wherein the filament is further operably coupled to the second filament rod proximate to the fourth end of the second filament rod. In one example, when viewed perpendicular to the second axis, the second filament rod is generally identical to the first filament rod when viewed perpendicular to the first axis.

In accordance with another example aspect of the disclosure, a cathode filament device for an indirectly heated cathode is provided having a first filament rod and a second filament rod. The first filament rod, for example, has a first end and a second end along a first axis, wherein the first filament rod comprises a first engagement portion proximate to the first end thereof, and wherein the first engagement portion comprises a first engagement body and a first positioning feature extending from the first engagement body. The second filament rod, for example, has a third end and a fourth end along a second axis, wherein the second filament rod comprises a second engagement portion proximate to the third end and having a second engagement body.

A first clamping member, for example, has a first clamping surface configured to selectively engage the first engagement body, wherein the first positioning feature is configured to limit a translation of the first filament rod with respect to the first clamping member in at least a first direction along the first axis. A second clamping member, for example, is configured to selectively engage the second engagement body. Further, a filament is operably coupled to the first filament rod proximate to the second end of the first filament rod and to the second filament rod proximate to the fourth end of the second filament rod.

The second filament rod, for example, when viewed perpendicular to the second axis, is substantially identical to the first filament rod when viewed perpendicular to the first axis. The first filament rod, for example, can further comprise a second positioning feature extending from the first engagement portion, wherein the second positioning feature is configured to limit a translation of the first filament rod with respect to the first clamping member in a second direction along the first axis, and wherein the second direction is opposite the first direction. The first positioning feature and the second positioning feature, for example, can respectively comprise one or more of a tab, a rod, a collar, a flange, and a step extending outwardly from the first engagement portion.

In another example, the first engagement portion defines a first diameter of the first filament rod, and wherein the first positioning feature and the second positioning feature define a second diameter of the first filament rod, wherein the second diameter is greater than the first diameter. The first engagement portion, for example, can be cylindrical having a first engagement diameter, wherein the first positioning feature comprises a first flange having a first positioning diameter, wherein the first positioning diameter is greater than the first engagement diameter. The first filament rod, for example, can further comprise a second positioning feature extending from the first engagement body, wherein the second positioning feature defines a filament rod diameter. The filament rod diameter, for example, is greater than the first engagement diameter, wherein the second positioning feature is configured to limit a translation of the first filament rod with respect to the first clamping member in a second direction along the first axis, and wherein the second direction is opposite the first direction.

The second engagement portion of the second filament rod, for example, can comprise a third positioning feature extending from the second engagement body, wherein the third positioning feature is configured to limit a translation of the second filament rod with respect to the second clamping member in at least the first direction along the second axis. The second filament rod, for example, can further comprise a fourth positioning feature extending from the second engagement body. The fourth positioning feature can define a filament rod diameter, and the second engagement body can define a second engagement diameter. The filament rod diameter, for example, can be greater than the second engagement diameter, wherein the fourth positioning feature is configured to limit a translation of the second filament rod with respect to the second clamping member in a second direction along the second axis, wherein the second direction is opposite the first direction.

In accordance with yet another example aspect of the disclosure, a cathode filament device for an indirectly heated cathode is provided, wherein the cathode filament device comprises a first filament rod having a first end and a second end along a first axis. The first filament rod, for example, comprises a first engagement portion proximate to the first end thereof, wherein the first engagement portion comprises a first engagement body and a first positioning feature and a second positioning feature extending from the first engagement body. A second filament rod, for example, has a third end and a fourth end along a second axis, wherein the second filament rod comprises a second engagement portion proximate to the third end, and wherein the second engagement portion comprises a second engagement body and a third positioning feature and a fourth positioning feature extending from the second engagement body.

A first clamping member, for example, has a first clamping surface configured to selectively engage the first engagement body, wherein the first positioning feature and second positioning feature are configured to limit a translation of the first filament rod with respect to the first clamping member along the first axis. A second clamping member, for example, is configured to selectively engage the second engagement body, wherein the third positioning feature and fourth engagement feature are configured to limit a translation of the second filament rod with respect to the second clamping member along the second axis. Further, a filament is operably coupled to the first filament rod proximate to the second end of the first filament rod and to the second filament rod proximate to the fourth end of the second filament rod.

One or more of the first positioning feature, the second positioning feature, the third positioning feature and the fourth positioning feature, for example, can comprise one or more of a tab, a rod, a collar, a flange, and a step respectively extending outwardly from the respective first engagement portion and the second engagement portion. One or more of the first positioning feature, the second positioning feature, the third positioning feature, and the fourth positioning feature, for example, are configured to generally fix a position of the filament with respect to one or more of the first clamping member and the second clamping member.

In accordance with still another example aspect of the disclosure, an indirectly heated cathode apparatus is provided, wherein the indirectly heated cathode apparatus comprises a cathode having a blind hole defined therein, wherein the blind hole extends along a cathode axis. A filament rod, for example, extends from a first end to a second end thereof, wherein the filament rod comprises a first engagement portion proximate to the first end and one or more positioning features extending outwardly from the first engagement portion. A filament is operably coupled to the filament rod proximate to the second end of the filament rod. A clamping member is further provided, wherein the clamping member has a clamping surface. The clamping member, for example, is configured to selectively clamp the first engagement portion of the filament rod to the clamping surface, wherein the one or more positioning features are further configured to selectively mate with the clamping member. As such, the filament is selectively positioned with respect to the cathode axis within the blind hole.

The one or more positioning features, for example, are configured to fixedly position the filament at an aligned position with respect to the cathode axis, whereby the aligned position defines a predetermined gap distance between the filament and a bottom surface of the blind hole of the cathode. In another example, the aligned position can further define a predetermined sidewall gap between the filament and an internal diameter of the blind hole of the cathode.

To the accomplishment of the foregoing and related ends, the disclosure comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 illustrates a cross-sectional view of an example configuration of an ion source having an indirectly heated cathode that is aligned via an external alignment tool.

FIG. 2 is a block diagram of an example vacuum system utilizing an ion source in accordance with several example aspects of the present disclosure.

FIG. 3 is a schematic view of an example arc chamber in accordance with several example aspects of the present disclosure.

FIG. 4 is a partial cross-sectional view of an example ion source in accordance with several example aspects of the present disclosure.

FIG. 5 is a partial cross-sectional elevation view of an example cathode filament device in accordance with various example aspects of the present disclosure.

FIG. 6 is a cross-sectional view of the example cathode filament device of FIG. 5, taken along the lines 6-6 of FIG. 5.

FIGS. 7-10 are respective elevation views of various cathode filament devices in accordance with various example aspects of the present disclosure.

FIG. 11 is a partial plan view of an example cathode filament clamp in accordance with various example aspects of the present disclosure.

FIG. 12 is a partial plan view of an example cathode filament device and a cathode filament clamp in accordance with various aspects of the present disclosure.

### DETAILED DESCRIPTION

The present disclosure is directed generally toward an ion implantation system and an ion source associated therewith. More particularly, the present disclosure provides a system, apparatus, and method for accurately positioning a cathode filament in an indirectly heated cathode in order to enhance a productivity, stability, and lifetime of the ion source. Accordingly, the present invention will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, elements or other physical or functional units shown in the drawings or described herein could also be implemented by an indirect connection or coupling. Furthermore, it is to be appreciated that functional blocks or units shown in the drawings may be implemented as separate features in one embodiment, and may also or alternatively be fully or partially implemented in a common feature in another embodiment.

Ion implantation is a process that is employed in semiconductor device fabrication in which ions of one or more elements are accelerated into a workpiece in order to change the properties of the workpiece. For example, it is common for dopants such as boron, arsenic, and phosphorus to be implanted into silicon to modify its electrical properties. In an exemplary ion implantation process, an element or molecule of interest is ionized, extracted, and accelerated electrostatically to form a high energy ion beam, filtered by its mass-to-charge ratio, and directed to strike a workpiece. The ions physically bombard the wafer, enter the surface and come to rest below the surface, at a depth related to their energy.

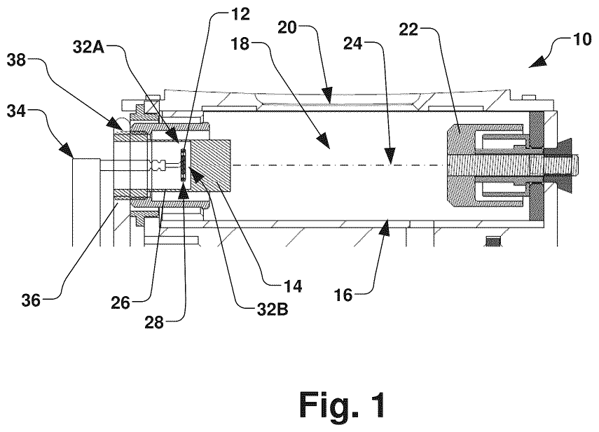

Referring now to the Figures, FIG. 1 illustrates a cross section of one possible configuration of an ion source 10 used in an ion implantation system. A filament 12 is resistively heated to a temperature at which thermionic emission of electrons occurs. A voltage (a so-called “cathode voltage”) between the filament 12 and a cathode 14 accelerates the emitted electrons from the filament toward the cathode until the cathode, itself, thermally emits electrons. Such an emission scheme is termed in the industry as an indirectly heated cathode (IHC). The cathode 14, for example, serves two purposes; namely, it protects the filament 12 from being bombarded by plasma ions, and it provides electrons for subsequent ionization.

The cathode 14 is biased negatively with respect to an arc chamber 16 in which it resides as a so-called “arc voltage”, and the emitted electrons are accelerated toward a center 18 of the arc chamber. A feed gas (not shown) is flowed into the arc chamber 16, and the emitted electrons subsequently ionize the feed gas, thus forming a plasma (not shown) from which ions can be extracted via an extraction slit 20 in the arc chamber. A repeller 22, for example, further charges up to the negative floating potential of the plasma and repels electrons back into the plasma, thus leading to enhanced ionization and a denser plasma. A magnetic field (not shown) that is parallel to a center axis 24 defined by the cathode 14 and repeller 22 generally confines the emitted and repelled electrons to define a so-called “plasma column”, thus improving ionization and plasma density even further.

Alignment of the filament 12 within the cathode 14 can play a significant role in the lifetime of the ion source 10. A common issue with the filament 12 and cathode 14 is premature failure of the filament, or so-called “side punch through” of the cathode, which is defined by a premature failure of a side wall 26 of the cathode due to a periphery 28 of the filament being misaligned with respect to the cathode. For example, if not aligned properly, gaps 32A, 32B between the filament 12 and cathode 14 can be inconsistent, thus causing variable heating and sputtering of the cathode 14, leading to failure of the cathode and/or the filament 12. Such failures decrease a lifetime and productivity of the ion source 10.

Conventionally, an external alignment fixture (not shown) is implemented in an attempt to position the filament 12 within the cathode 14. The filament 12, for example, is placed in a clamp 34, and using the external alignment fixture, the fixture sets a radial position (associated with gap 32A) and axial position (associated with gap 32B) of the filament with respect to the clamp 34. Once the radial and axial positions are set, the external alignment fixture is removed and the cathode 14 is threaded onto a holder 36 via threads 38, whereby the gap 32B is finally set based on how far the cathode is threaded onto the holder. The cathode 14, for example, is threaded onto the holder 36 until the cathode touches the filament 12, thus creating electrical continuity between the cathode and filament. Once electrical continuity is detected, the cathode 14 is unthreaded a predetermined number of turns to set the gap 32B, whereby the gap 32B is based on the number of turns and a thread pitch of the threads 38 between the cathode and holder 36.

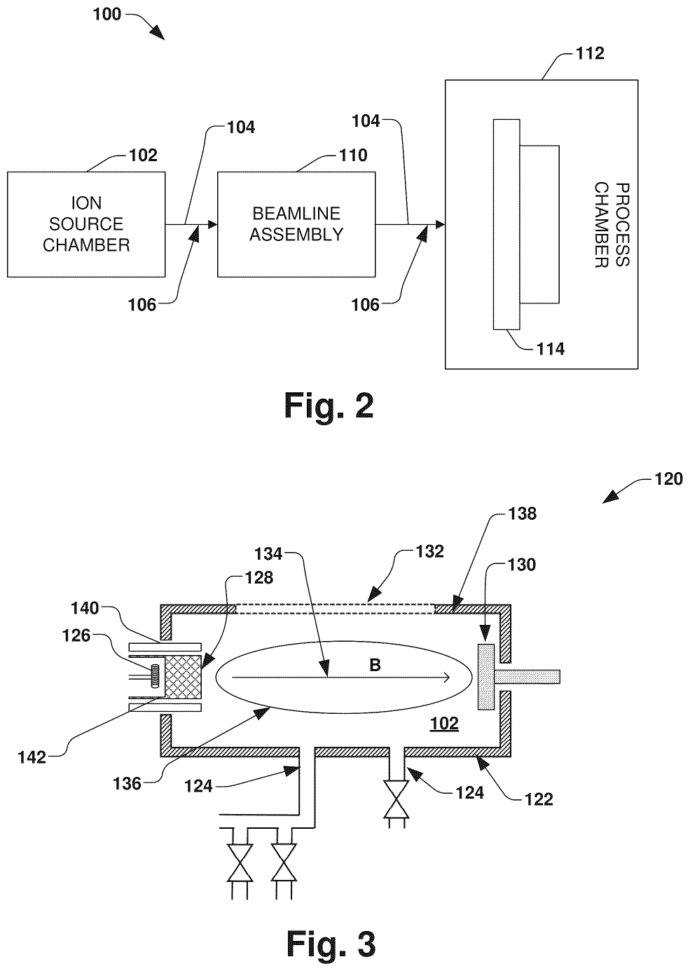

FIG. 2 illustrates a system 100 in accordance with the present disclosure, wherein the system includes an ion source 102 for producing an ion beam 104 along a beam path 106. A beamline assembly 110 is provided downstream of the ion source 102 to receive a beam therefrom. The beamline assembly 110 may include (not shown) a mass analyzer, an acceleration structure, which may include, for example, one or more gaps, and an angular energy filter. The mass analyzer includes a field generating component, such as a magnet, and operates to provide a field across the beam path 106 so as to deflect ions from the ion beam 104 at varying trajectories according to mass (e.g., mass-to-charge ratio). Ions traveling through the magnetic field experience a force which directs individual ions of a desired mass along the beam path 106 and which deflects ions of undesired mass away from the beam path.

A process chamber 112 is provided in the system 100, which contains a target location that receives the ion beam 104 from the beamline assembly 110 and supports one or more workpieces 114 such as semiconductor wafers along the beam path 106 for implantation using the final mass analyzed ion beam. The process chamber 112 then receives the ion beam 104 which is directed toward a workpiece 114. It is appreciated that different types of process chambers 112 may be employed in the system 100. For example, process chamber 112 can be a “batch” type configured to simultaneously support multiple workpieces 114 on a rotating support structure, wherein the workpieces 114 are rotated through the path of the ion beam 104 until all the workpieces 114 are completely implanted. Alternatively, the process chamber 112 can be a “serial” type that is configured to support a single workpiece 114 along the beam path 106 for implantation, wherein multiple workpieces 114 are implanted one at a time in serial fashion, with each workpiece being completely implanted before implantation of the next workpiece begins. The system 100 may also include a scanning apparatus (not shown) for moving the ion beam 104 with respect to the workpiece 114, or the workpiece with respect to the ion beam.

The ion source 102, for example, generates the ion beam 104 by ionizing a source gas containing a desired dopant element within the ion source. The ionized source gas is subsequently extracted from a source chamber (e.g., an arc chamber) of the ion source 102 in the form of the ion beam 104. The ionization process is effected by an exciter which may take the form of a thermally heated filament, a filament heating a cathode (indirectly heated cathode “IHC”), or a radio frequency (RF) antenna.

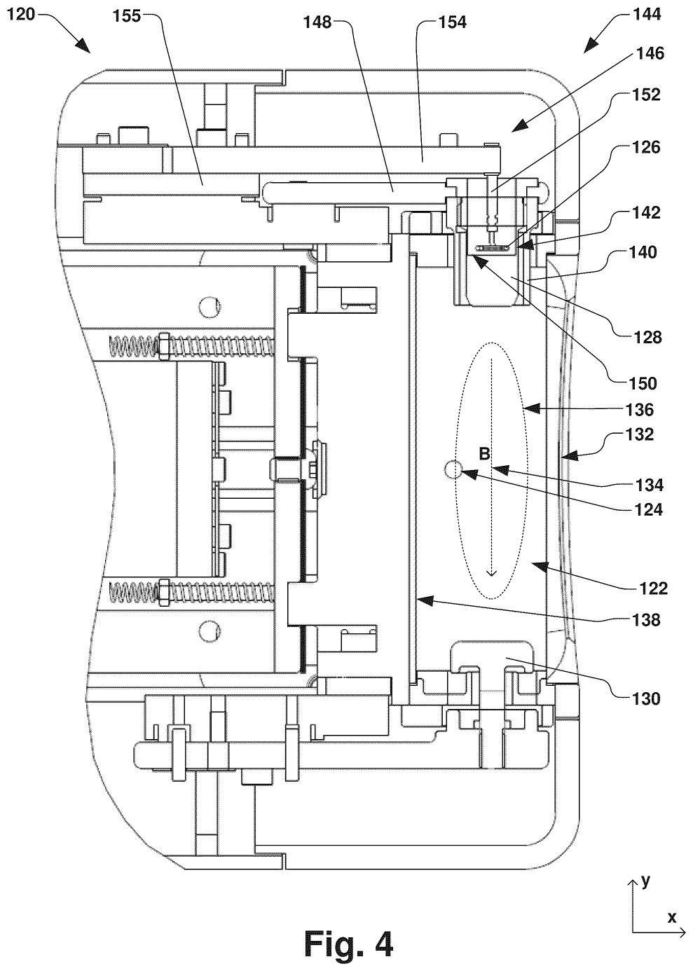

The ion source 102, for example, is illustrated schematically as an IHC ion source 120 in FIGS. 3-4, for example, wherein the IHC ion source comprises a source chamber 122, one or more gas inlets 124, a filament 126, a cathode 128 and a repeller 130 positioned opposite of one another in the source chamber, and an aperture 132 (also called an arc slit). In addition, a source magnet (not illustrated) can provide a magnetic field 134 generally along an axis between the cathode 128 and repeller 130. During operation of the IHC ion source 120, the filament 126 is resistively heated to temperatures high enough to emit electrons, which are in turn accelerated to bombard the cathode 128 which is maintained at a potential that is positive with respect to the filament.

The electron bombardment heats the cathode 128 to temperatures high enough for it to thermally emit electrons into the source chamber 122 which is held at a potential that is positive with respect to the cathode 128 to accelerate the electrons. The magnetic field 134 helps confine the electrons along the field lines between the cathode 128 and repeller 130 along a plasma column 136 in order to reduce the loss of electrons to chamber walls 138 of the source chamber 122. The loss of electrons is further reduced by the repeller 130 which is typically at the potential of the cathode 128 to reflect electrons back toward the cathode. A cathode shield 140 also generally limits exposure of a thin sidewall 142 of the cathode 128 to the plasma column 136. The excited electrons ionize a source gas which is fed into the chamber through the gas inlet 124, generating a plasma. Ions are extracted through the aperture 132 and electrostatically accelerated to form a high energy ion beam by an electrode positioned outside the source chamber 122.

This present disclosure appreciates that accurate alignment of the filament 126 with respect to the cathode 128 can play a significant role in the lifetime of the IHC ion source 120, whereby inaccurate alignment can lead to punch-through of the thin sidewall 142 due to uneven thermionic reaction along the thin sidewall. Thus, as will be appreciated in the following discussion, the present disclosure advantageously increases a lifetime of the IHC ion source 120 by reducing alignment errors between the filament 126 and the cathode 128 when the ion source is assembled.

While various configurations of the IHC ion source 120 will be discussed in greater detail infra, it should be noted that the examples described herein are illustrative of just several non-limiting configurations of the IHC ion source 120 of FIGS. 3-4, and that various other configurations are also contemplated as falling within the scope of the present disclosure.

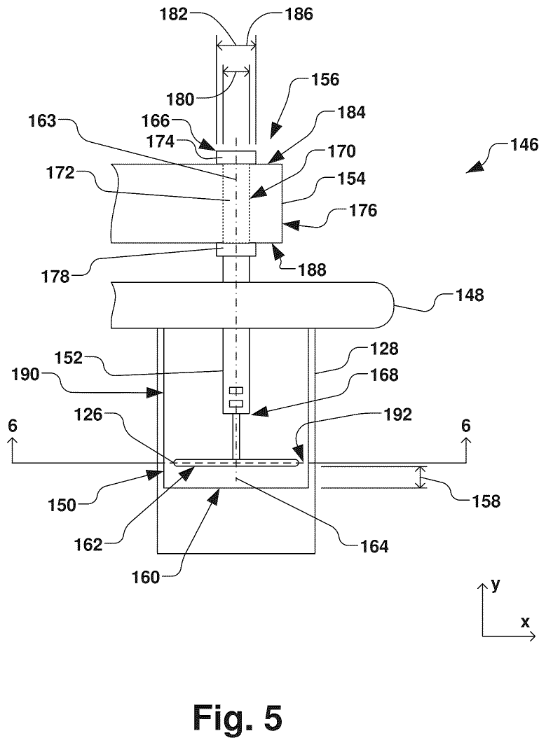

As shown in the examples provided in FIGS. 4-5, the IHC ion source 120 of FIG. 4 comprises a cathode apparatus 146, whereby the cathode 128 is operably coupled to a cathode base 148. In one example, the cathode base 148 is comprised of graphite, and the cathode 128 is comprised of a metal compatible with ion implantation, such as tungsten. According to one example, the filament 126 is selectively positioned within a blind hole 150 defined in the cathode 128 via a filament rod 152 that is selectively fixed in position via a filament clamp 154. The filament clamp 154, for example, is fixedly positioned with respect to the cathode base 148 via one or more insulating spacers 155, whereby the one or more insulating spacers electrically insulate the filament clamp from the cathode base. A filament power source (not shown) may be coupled to the filament clamp 154, and whereby a cathode power source (not shown) may be electrically coupled to the cathode base 148. According to one example, the cathode apparatus 146 can comprise any number of features, such as those provided in co-owned U.S. patent application Ser. No. 17/876,812, now US Patent Application Publication US20240038490, the contents of which are hereby incorporated by reference herein.

As illustrated in an example of a cathode filament device 156 shown in FIG. 5, the filament 126 is operably coupled to the filament rod 152, whereby the filament clamp 154 is configured to selectively fix the filament at a predetermined gap distance 158 from a bottom surface 160 of the cathode 128 within the blind hole 150 of the cathode. In accordance various aspects of the disclosure, the cathode filament device 156 is defined by at least the filament rod 152 and the filament 126.

The present disclosure appreciates the filament 126 is a consumable component, and that the predetermined gap distance 158 between the filament and the bottom surface 160 of the cathode 128 can affect a lifetime of the cathode, and thus the ion source. As such, the cathode filament device 156 of the present disclosure, in conjunction with the filament clamp 154, is configured to consistently provide an aligned position 162 of the filament 126 along or with respect to a cathode axis 163 defined by the blind hole 150. Accordingly, the predetermined gap distance 158 between the filament 126 and the bottom surface 160 of the cathode 128 can be maintained by the cathode filament device 156 without the need for additional external alignment mechanisms.

The filament rod 152, for example, has a first end 166 and a second end 168 generally defined along a first axis 164. The first axis 164 and the cathode axis 163, for example, can be parallel to one another, or colinear. According to one example, the filament rod 152 comprises a first engagement portion 170 proximate to the first end 166, wherein the first engagement portion comprises a first engagement body 172 and a first positioning feature 174 extending from the first engagement body. The filament 126, for example, is further operably coupled to the filament rod 152 proximate to the second end 168 of the filament rod.

According to one example, the filament clamp 154 defines a clamping member 176 of the cathode filament device 156, wherein the first engagement body 172 is configured to selectively mate with the clamping member, as will be discussed in greater detail infra. The first positioning feature 174, for example, is configured to limit a translation of the filament rod 152 with respect to the clamping member 176 in at least a first direction (e.g., the −y direction) along the first axis 164. The filament rod 152, for example, can further comprise a second positioning feature 178 extending from the first engagement body 172, wherein the second positioning feature is configured to limit a translation of the filament rod with respect to the clamping member 176 in a second direction (e.g., the +y direction) along the first axis 164. The second direction, for example, is opposite the first direction.

In one example, the first engagement portion 170 of the filament rod 152 defines a first engagement diameter 180, wherein the first positioning feature 174 defines a first positioning diameter 182, wherein the first positioning diameter is greater than the first engagement diameter. Accordingly, in the present example, at least the first positioning feature 174 is configured to contact a first clamping surface 184 of the filament clamp 154 in the aligned position 162 of the filament 126 along the first axis 164. The second positioning feature 178, for example, may further define a second positioning diameter 186 and may be further configured to contact a second clamping surface 188 of the filament clamp 154 in the aligned position 162 of the filament 126 along the first axis 164. In the present example shown in FIG. 5, the first positioning diameter 182 and the second positioning diameter 186 are equal. However, the present disclosure contemplates the first positioning diameter 182 differing from the second positioning diameter 186 in other examples. Accordingly, one or more of the first positioning feature 174 and the second positioning feature 178 are thus configured to provide the desired alignment of the filament 126 along the first axis 164 when the filament rod 152 is clamped by the filament clamp 154.

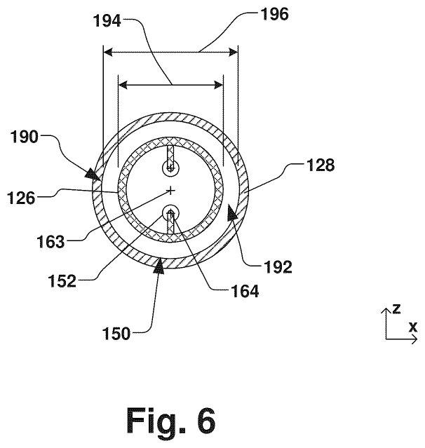

Further, the cathode apparatus 146 is configured to maintain concentricity between the filament 126 a sidewall 190 of the cathode 128 within the blind hole 150 of the cathode in order to consistently maintain a predetermined sidewall gap 192 between the filament and the sidewall of the cathode when viewed along the cathode axis 163. For example, as illustrated in FIG. 6, the filament 126 generally defines a filament diameter 194 thereof, whereby the predetermined sidewall gap 192 is approximately constant between the filament and an internal diameter 196 of the cathode 128 when viewed along the cathode axis 163.

The filament 126, for example, is generally defined by a circumscribed circle about a periphery thereof when viewed along the cathode axis 163, thereby defining the filament diameter 194 about the circumscribed circle, as seen in FIG. 6. The filament 126 in the present example is generally circular, however other shapes are also contemplated as falling within the scope of the present disclosure. The blind hole 150 in the cathode 128, for example, defines the internal diameter 196, wherein the internal diameter of the cathode is greater than the filament diameter 194. As such, the present disclosure provides a coaxial alignment of the filament 126 within the blind hole 150 of the cathode 128, thus providing a consistency of the predetermined sidewall gap 192 between the filament and the sidewall 190 of the cathode, as well as consistently providing the predetermined gap distance 158 between the filament and the bottom surface 160 of the cathode, thus improving a lifetime of the cathode, and thus the ion source.

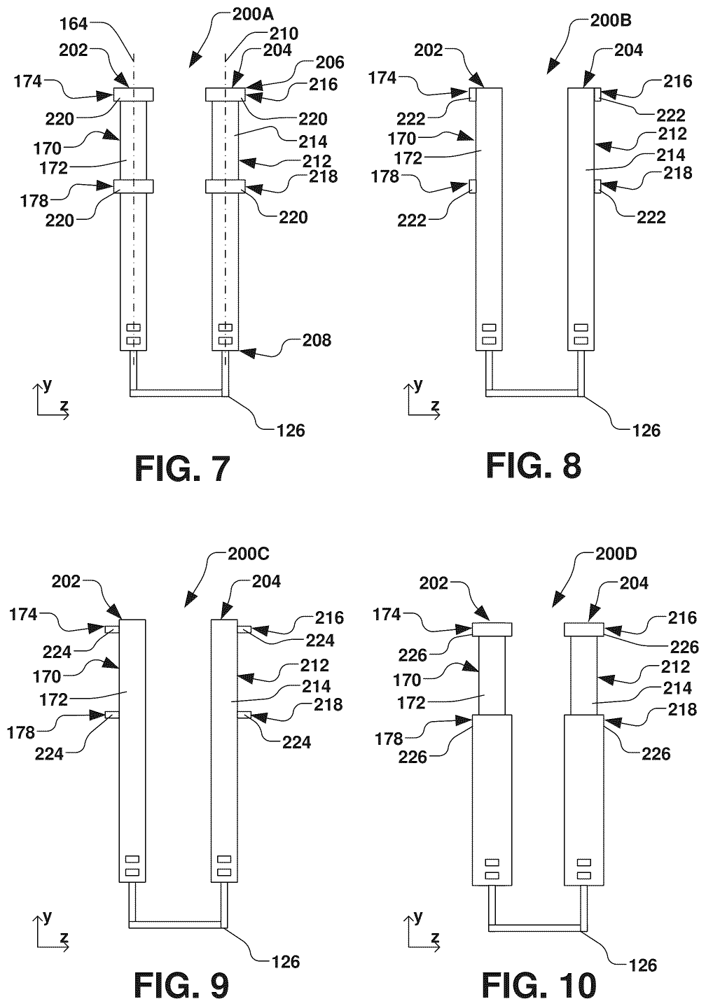

The present disclosure, for example, contemplates the filament 126 of the cathode filament device 156 of FIGS. 5 and 6 as being electrically coupled to any number of filament rods 152, whereby the filament clamp 154 is configured to selectively clamp the filament rod(s) thereto. For example, FIGS. 7-10 illustrate various cathode filament devices 200A-200D in various configurations. The filament device 200A, for example, comprises a first filament rod 202 and a second filament rod 204 operably coupled to a filament 126. In the present example, the first filament rod 202 and the second filament rod 204 in the present example are substantially similar or identical to one another. However, the present disclosure contemplates the first filament rod 202 and second filament rod 204 differing from one another, as well. One or more of the first filament rod 202 and the second filament rod 204 of the filament device 200A of FIG. 7, for example, are substantially similar to the filament rod 152 of FIG. 5.

The second filament rod 204 illustrated in FIG. 7, for example, has a third end 206 and a fourth end 208 along a second axis 210. The second axis 210, for example, is parallel to the first axis 164. The second filament rod 204, for example, has a second engagement portion 212 having a second engagement body 214 proximate to the third end 206. The filament 126, for example, is further operably coupled to the second filament rod 204 proximate to the fourth end 208 of the second filament rod. The second filament rod 204, for example, further comprises a third positioning feature 216 and a fourth positioning feature 218 configured to contact the respective first clamping surface 184 and second clamping surface 188 of the filament clamp 154 of FIG. 5 in a manner similar to that discussed relative to the filament rod 152. In one example, when viewed perpendicular to the second axis 210, the second filament rod 204 is generally identical to the first filament rod 202 when viewed perpendicular to the first axis 164.

In the present example, one or more of the first positioning feature 174, second positioning feature 178, third positioning feature 216, and fourth positioning feature 218 for example, respectively comprise a collar or a flange 220 extending outwardly from the respective first engagement body 172 and second engagement body 214. Each collar or flange 220, for example, may have similar or differing diameters with respect to one another.

FIG. 8, for example, illustrates the filament device 200B, whereby one or more of the first positioning feature 174, second positioning feature 178, third positioning feature 216, and fourth positioning feature 218 respectively comprise a tab 222 extending outwardly from the respective first engagement body 172 and second engagement body 214. FIG. 9 illustrates another example, whereby one or more of the first positioning feature 174, second positioning feature 178, third positioning feature 216, and fourth positioning feature 218 of the filament device 200C respectively comprise a rod or pin 224 extending outwardly from the respective first engagement body 172 and second engagement body 214. FIG. 10 illustrates another example, one or more of the first positioning feature 174, second positioning feature 178, third positioning feature 216, and fourth positioning feature 218 of the filament device 200D comprise a step 226 extending outwardly from the respective first engagement body 172 and second engagement body 214.

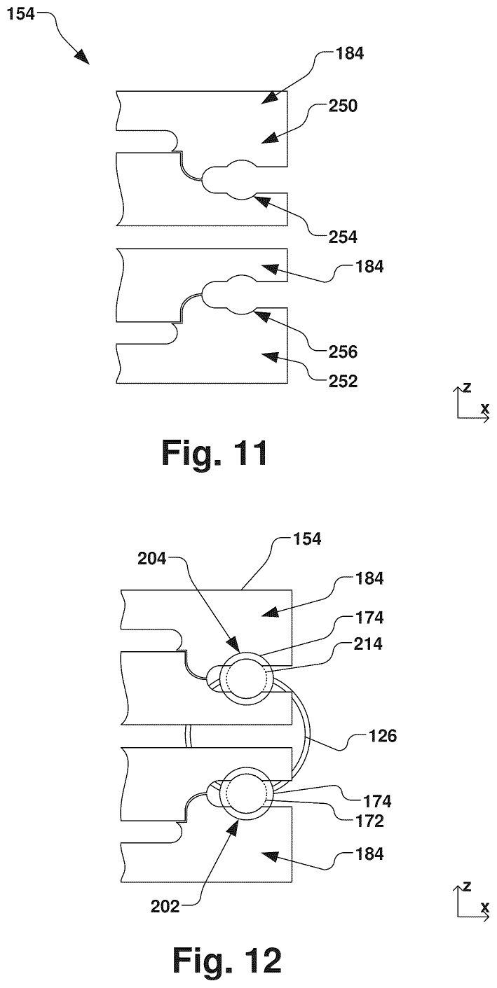

FIG. 11 illustrates another example of the present disclosure, whereby the filament clamp 154 is illustrated. The filament clamp 154, for example, comprises first and second clamping members 250, 252 configured to respectively engage and clamp the first engagement body 172 and the second engagement body 214 of the filament devices 200A-200D of FIGS. 6-9 in a respective clamp receiver 254, 256. As illustrated in FIG. 12, when clamped to the filament clamp 154, the first clamping surface 184 of the filament clamp, for example, is configured to contact at least the first positioning feature 174 of the respective first and second filament rods 202, 204.

Accordingly, the present disclosure provides low tolerance stacks between the filament, filament clamp, cathode, and cathode holder, whereby accurate positioning of the filament with respect to the cathode is advantageously repeatable from assembly to assembly.

Although the invention has been shown and described with respect to a certain embodiment or embodiments, it should be noted that the above-described embodiments serve only as examples for implementations of some embodiments of the present invention, and the application of the present invention is not restricted to these embodiments. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application. Accordingly, the present invention is not to be limited to the above-described embodiments, but is intended to be limited only by the appended claims and equivalents thereof.

1. A cathode filament device for an indirectly heated cathode, the cathode filament device comprising:
a first filament rod having a first end and a second end along a first axis, wherein the first filament rod comprises a first engagement portion proximate to the first end thereof, wherein the first engagement portion comprises a first engagement body and a first positioning feature extending from the first engagement body; and
a filament operably coupled to the first filament rod proximate to the second end of the first filament rod.

2. The cathode filament device of claim 1, further comprising a first clamping member, wherein the first engagement body is configured to selectively mate with the first clamping member, and wherein the first positioning feature is configured to limit a translation of the first filament rod with respect to the first clamping member in at least a first direction along the first axis.

3. The cathode filament device of claim 2, wherein the first filament rod further comprises a second positioning feature extending from the first engagement portion, wherein the second positioning feature is configured to limit a translation of the first filament rod with respect to the first clamping member in a second direction along the first axis, wherein the second direction is opposite the first direction.

4. The cathode filament device of claim 3, wherein the first positioning feature and the second positioning feature comprise one or more of a tab, a rod, a collar, a flange, and a step extending outwardly from the first engagement portion.

5. The cathode filament device of claim 3, wherein the first engagement portion defines a first diameter of the first filament rod, and wherein the first positioning feature and the second positioning feature define a second diameter of the first filament rod, wherein the second diameter is greater than the first diameter.

6. The cathode filament device of claim 2, wherein the first engagement portion is cylindrical having a first engagement diameter, and wherein the first positioning feature comprises a first flange having a first positioning diameter, wherein the first positioning diameter is greater than the first engagement diameter.

7. The cathode filament device of claim 6, wherein the first filament rod further comprises a second positioning feature extending from the first engagement body, wherein the second positioning feature defines a second positioning diameter, wherein the second positioning diameter is greater than the first engagement diameter, and wherein the second positioning feature is configured to limit a translation of the first filament rod with respect to the first clamping member in a second direction along the first axis, wherein the second direction is opposite the first direction.

8. The cathode filament device of claim 1, further comprising a second filament rod having a third end and a fourth end along a second axis, wherein the second filament rod comprises a second engagement portion proximate to the third end, and wherein the filament is operably coupled to the second filament rod proximate to the fourth end of the second filament rod.

9. The cathode filament device of claim 8, wherein the second filament rod, when viewed perpendicular to the second axis, is identical to the first filament rod when viewed perpendicular to the first axis.

10. A cathode filament device for an indirectly heated cathode, the cathode filament device comprising:
a first filament rod having a first end and a second end along a first axis, wherein the first filament rod comprises a first engagement portion proximate to the first end thereof, wherein the first engagement portion comprises a first engagement body and a first positioning feature extending from the first engagement body;
a second filament rod having a third end and a fourth end along a second axis, wherein the second filament rod comprises a second engagement portion proximate to the third end and having a second engagement body;
a first clamping member having a first clamping surface configured to selectively engage the first engagement body, and wherein the first positioning feature is configured to limit a translation of the first filament rod with respect to the first clamping member in at least a first direction along the first axis;
a second clamping member configured to selectively engage the second engagement body; and
a filament operably coupled to the first filament rod proximate to the second end of the first filament rod and to the second filament rod proximate to the fourth end of the second filament rod.

11. The cathode filament device of claim 10, wherein the second filament rod, when viewed perpendicular to the second axis, is substantially identical to the first filament rod when viewed perpendicular to the first axis.

12. The cathode filament device of claim 10, wherein the first filament rod further comprises a second positioning feature extending from the first engagement portion, wherein the second positioning feature is configured to limit a translation of the first filament rod with respect to the first clamping member in a second direction along the first axis, wherein the second direction is opposite the first direction.

13. The cathode filament device of claim 12, wherein the first positioning feature and the second positioning feature comprise one or more of a tab, a rod, a collar, a flange, and a step extending outwardly from the first engagement portion.

14. The cathode filament device of claim 12, wherein the first engagement portion defines a first diameter of the first filament rod, and wherein the first positioning feature and the second positioning feature define a second diameter of the first filament rod, wherein the second diameter is greater than the first diameter.

15. The cathode filament device of claim 10, wherein the first engagement portion is cylindrical having a first engagement diameter, and wherein the first positioning feature comprises a first flange having a first positioning diameter, wherein the first positioning diameter is greater than the first engagement diameter.

16. The cathode filament device of claim 15, wherein the first filament rod further comprises a second positioning feature extending from the first engagement body, wherein the second positioning feature defines a filament rod diameter, wherein the filament rod diameter is greater than the first engagement diameter, and wherein the second positioning feature is configured to limit a translation of the first filament rod with respect to the first clamping member in a second direction along the first axis, wherein the second direction is opposite the first direction.

17. The cathode filament device of claim 10, wherein the second engagement portion of the second filament rod comprises a third positioning feature extending from the second engagement body, wherein the third positioning feature is configured to limit a translation of the second filament rod with respect to the second clamping member in at least the first direction along the second axis.

18. The cathode filament device of claim 17, wherein the second filament rod further comprises a fourth positioning feature extending from the second engagement body, wherein the fourth positioning feature defines a filament rod diameter, wherein the second engagement body defines a second engagement diameter, and wherein the filament rod diameter is greater than the second engagement diameter, wherein the fourth positioning feature is configured to limit a translation of the second filament rod with respect to the second clamping member in a second direction along the second axis, wherein the second direction is opposite the first direction.

19. A cathode filament device for an indirectly heated cathode, the cathode filament device comprising:
a first filament rod having a first end and a second end along a first axis, wherein the first filament rod comprises a first engagement portion proximate to the first end thereof, wherein the first engagement portion comprises a first engagement body and a first positioning feature and a second positioning feature extending from the first engagement body;
a second filament rod having a third end and a fourth end along a second axis, wherein the second filament rod comprises a second engagement portion proximate to the third end, wherein the second engagement portion comprises a second engagement body and a third positioning feature and a fourth positioning feature extending from the second engagement body;
a first clamping member having a first clamping surface configured to selectively engage the first engagement body, and wherein the first positioning feature and second positioning feature are configured to limit a translation of the first filament rod with respect to the first clamping member along the first axis;
a second clamping member configured to selectively engage the second engagement body, wherein the third positioning feature and fourth engagement feature are configured to limit a translation of the second filament rod with respect to the second clamping member along the second axis; and
a filament operably coupled to the first filament rod proximate to the second end of the first filament rod and to the second filament rod proximate to the fourth end of the second filament rod.

20. The cathode filament device of claim 19, wherein one or more of the first positioning feature, the second positioning feature, the third positioning feature and the fourth positioning feature comprise one or more of a tab, a rod, a collar, a flange, and a step extending outwardly from the respective first engagement portion and the second engagement portion.

21. The cathode filament device of claim 19, wherein one or more of the first positioning feature, the second positioning feature, the third positioning feature, and the fourth positioning feature are configured to fix a position of the filament with respect to one or more of the first clamping member and the second clamping member.

22. An indirectly heated cathode apparatus, comprising:
a cathode having a blind hole defined therein, wherein the blind hole extends along a cathode axis;
a filament rod extending from a first end to a second end thereof, wherein the filament rod comprises:
a first engagement portion proximate to the first end; and
one or more positioning features extending outwardly from the first engagement portion;
a filament operably coupled to the filament rod proximate to the second end of the filament rod; and
a clamping member having a clamping surface, wherein the clamping member is configured to selectively clamp the first engagement portion of the filament rod to the clamping surface, and wherein the one or more positioning features are further configured to selectively mate with the clamping member, thereby selectively positioning the filament with respect to the cathode axis within the blind hole.

23. The indirectly heated cathode apparatus of claim 22, wherein the one or more positioning features comprise one or more of a tab, a rod, a collar, a flange, and a step extending outwardly from the first engagement portion.

24. The indirectly heated cathode apparatus of claim 22, wherein the one or more positioning features are configured to fixedly position the filament at an aligned position with respect to the cathode axis, whereby the aligned position defines a predetermined gap distance between the filament and a bottom surface of the blind hole of the cathode.

25. The indirectly heated cathode apparatus of claim 24, wherein the aligned position further defines a predetermined sidewall gap between the filament and an internal diameter of the blind hole of the cathode.
